(19) United States
(12) Patent Application Publication
(10) Pub. No.: US 2005/0285253 A1
(43) Pub. Date: Dec. 29, 2005

(54) Forming buried via hole substrates

(76) Inventor: Kumamoto Takashi, Tsukuba (JP)

Correspondence Address: TROP PRUNER & HU, PC, 8554 KATY FREEWAY, SUITE 100, HOUSTON, TX, 77024, US

(21) Appl. No.: 10/876,434

(22) Filed: Jun. 24, 2004

(51) Int. Cl. H01L 23/053; H01L 21/4763

(52) U.S. Cl. 257/698; 257/700; 438/629; 257/784

(57) ABSTRACT

A preformed copper plug may be inserted into a via hole in a package substrate. The opposed surfaces of the copper preform may be covered with a solder material. Copper foils may then be applied over the core and over the preformed plug. A vacuum hot press method may be utilized to activate or cure adhesive between the foil and the core to adhesively secure the foil to the core. At the same time, the heat from the vacuum hot press method may solder the copper foil to the solder coated copper plug. Thus, in some embodiments, the difficulty of filling via holes in situ with plated copper may be reduced, increasing throughput and reducing cost in some cases.

### BACKGROUND

This invention relates generally to packaging integrated circuits.

Integrated circuits may be packaged in association with a substrate. One such substrate is the so-called flexible or flex substrate or flex tape. In addition, a variety of organic substrates may be utilized for packaging integrated circuits. One type of organic substrate uses bismaleimide-triazine (BT) resin.

In many cases it is desirable to make via holes through package substrates. This allows electrical connections through the substrate. Conventionally, the hole is filled with a copper material. It is necessary that the copper fill be void free. If the fill is not void free, the filled substrate may be unusable. Thus, it is necessary to plate the substrate through holes with a high degree of precision, resulting in lower throughput. As an alternative, conductive paste may be considered for use to plug via holes instead of copper plating. However, concerns about reliability and electrical resistance stability of conductive paste filled vias have prevented their use for integrated circuit packaging applications.

Thus, there is a need for better ways to make via holes for integrated circuit packaging.

### BRIEF DESCRIPTION OF THE DRAWINGS

FIG. 1 is an enlarged, cross-sectional view of one embodiment of the present invention;

FIG. 2 is an enlarged, cross-sectional view at an early stage of manufacture in accordance with one embodiment of the present invention;

FIG. 3 is an enlarged, cross-sectional view at a subsequent stage of manufacture in accordance with one embodiment of the present invention;

FIG. 4 is an enlarged, cross-sectional view at a subsequent stage of manufacture in accordance with one embodiment of the present invention;

FIG. 5 is an enlarged, cross-sectional view at a subsequent stage of manufacture in accordance with one embodiment of the present invention;

FIG. 6 is an enlarged, cross-sectional view at a subsequent stage of manufacture in accordance with one embodiment of the present invention; and

FIG. 7 is an enlarged, cross-sectional view of an integrated circuit package according to one embodiment of the present invention.

### DETAILED DESCRIPTION

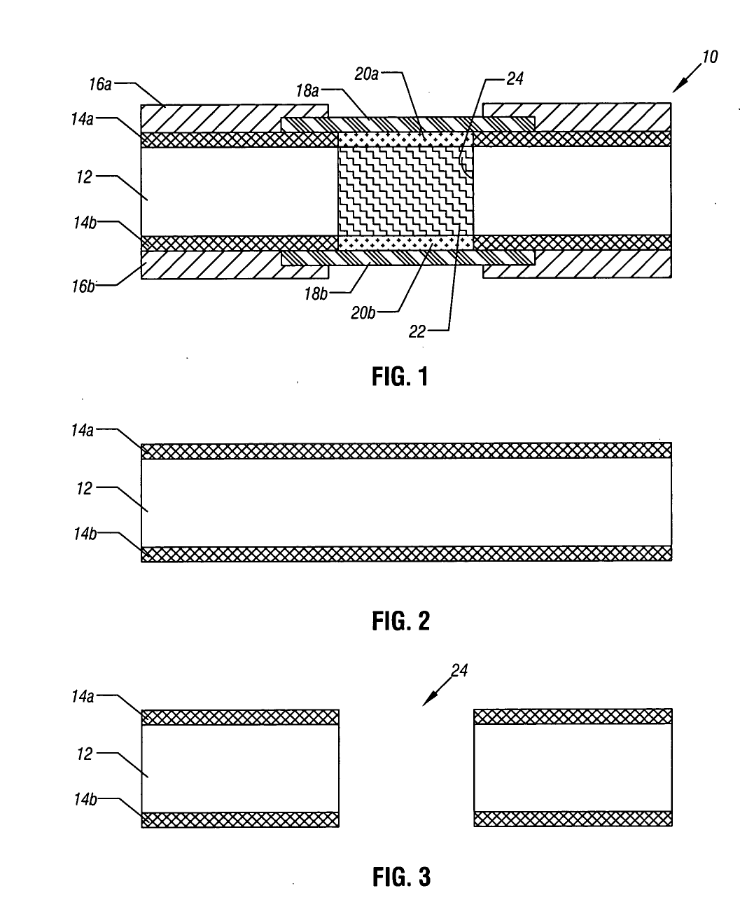

Referring to FIG. 1, a package substrate 10 such as a BT or flex substrate may include a core 12. The substrate 10 may be rigid or flexible. In one embodiment, the core material may be polymer, BT, epoxy, or polyimide, to mention a few examples. The thickness of the core may, for example, be from 25 to 200 microns. The core 12 may be filled with a copper column 22. Above the core 12 is a cured adhesive layer 14a and below the core is another cured adhesive layer 14b. The adhesive layers 14a and 14b may, for example, be a cured adhesive such as B-stage thermoset adhesive film laminated on both sides of the core 12.

Between the adhesive layers 14a and 14b and over the copper column 22 is a tin or solder surface layer 20a and 20b. The solder layers 20a and 20b may be preformed as a layer on the copper column 22, in one embodiment of the present invention. Over the solder layers 20a and 20b are copper foil layers 18a and 18b. Solder resist 16a and 16b may be applied over the resulting structure.

The copper column 22 with the tin or solder surface layers 20a and 20b may be punched from a sheet of such material. The sheet may be formed of void-free copper covered with the solder surface layers 20a and 20b. The punched out plug may then be inserted as a unit into the via 24 within the core 12.

As a result of the use of a preform, the need for tight process control when filling the via 24 in the core 12 is reduced. The losses from ruined substrates 10, caused by poor copper fills, is also reduced because the copper column 22 may be pretested before it is punched out and/or before it is placed into the via 24 in the core 12. Likewise, the reliability problems of using conductive paste may be avoided.

Referring to FIG. 2, an unpunched core material 12 may be coated with uncured adhesive layers 14a and 14b. For example, B-stage adhesive films may be laminated on opposed sides of the core 12.

Then, the coated core 12 is through punched to form the via 24 shown in FIG. 3. The punching may be done in one step, penetrating through both the uncured adhesive layers 14a and 14b and the core 12. The diameter of the via 24 may, for example, be from 100 to 300 microns.

A copper column 22 may be punched of an appropriate diameter from a sheet of appropriate thickness. That sheet may include solder surface layers 20a and 20b so that the entire unit, including the column 22 and the solder layers 20a and 20b, may be punched from the sheet and inserted as a unit into the via 24 in the core 12. In one embodiment, the copper column 22 with the solder surface layers 20a and 20b may be slightly thicker than the adhesive laminated core 12.

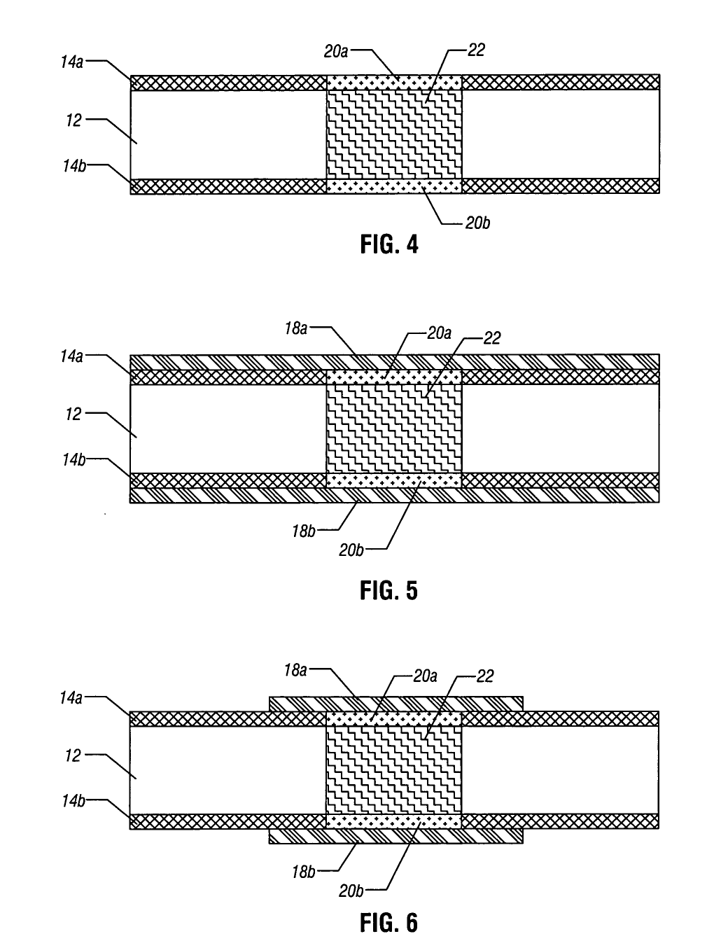

As shown in FIG. 4, the via 24 is filled with the column 22 coated with the solder surface layers 20a and 20b. In one embodiment, the solder surface layers 20a and 20b may include tin or lead free solder. The solder surface layers 20a and 20b may be from 1 to 20 microns thick in one embodiment of the present invention. Instead of solder, tin plating surface finishing may be used in one embodiment. The column 22 may be press fit into the via 24 in one embodiment.

Then, as shown in FIG. 5, copper foils 18a and 18b may be laminated on both sides of the structure shown in FIG. 4. A vacuum hot press method may be utilized to laminate the copper foils 18a and 18b on the FIG. 4 structure. In one embodiment, the copper foil 18 thickness may be 3 to 20 microns. During the hot press process, the uncured adhesive 14a and 14b is cured by the heat of the hot press. The copper foil 18a and 18b and the core 12 are also bonded by the adhesive 14a and 14b. During the hot press process, a copper-solder-copper diffusion layer is created by the heat of the hot press. The copper foil 18 and copper column 22 are solder bonded by this diffusion layer.

Copper trace processes may follow. In the case of an additive process, the copper foil thickness may be about 3 microns and in the case of a subtractive process, the copper foil may be 9 to 20 microns. Solder resist may then be applied as indicated at 16a and 16b in FIG. 1.

Because the via hole 24 is plugged by the copper column 22 and then covered by the copper foils 18, a solder ball pad or blind via pad can be laid out directly over the via 24.

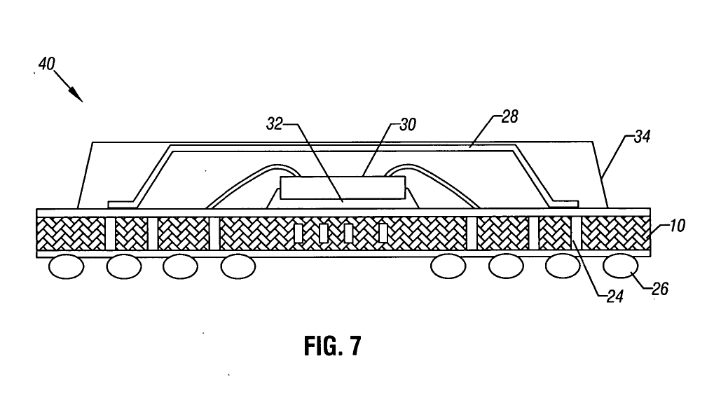

Referring to FIG. 7, an integrated circuit package 40 includes the substrate 10. The substrate 10 may include a plurality of vias 24 formed therein as described previously herein. The substrate 10 may, in one embodiment, have solder balls 26 for electrically coupling to electrical connections through the via 24. A heat spreader 28 may be embedded within a mold 34. A die 30 is positioned under the heat spreader 28 within the mold 34. A die attach epoxy 32 attaches the die to the substrate 10 in one embodiment.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
filling a via in an integrated circuit package substrate core with a preformed plug.

2. The method of claim 1 including forming a preform plug by cutting it from a sheet of material.

3. The method of claim 2 including cutting said plug from a sheet of material, said plug having a preformed solder surface.

4. The method of claim 1 including applying an uncured adhesive to said substrate core.

5. The method of claim 4 including punching a hole through said uncured adhesive and said substrate core.

6. The method of claim 5 including placing said preformed plug in said via.

7. The method of claim 6 including laminating a metal foil over said plug and said adhesive on said core.

8. The method of claim 7 including heating to cure said adhesive and to adhesively bond said metal foil to said core.

9. The method of claim 7 including heating to solder said metal foil to said plug.

10. The method of claim 1 including securing a preformed copper plug within said via in an integrated circuit package.

11. A substrate for an integrated circuit package comprising:
a core;
a via formed through said core;
a metal plug in said via; and
a metal foil on opposite sides of said core, said metal foil soldered to said plug.

12. The substrate of claim 11 including an adhesive between said foil and said core.

13. The substrate of claim 12 wherein said adhesive is cured.

14. The substrate of claim 11 wherein said plug is a copper plug and said metal foil is a copper foil.

15. The substrate of claim 11 wherein said plug includes a solder material formed on opposed ends of said plug.

16. An integrated circuit package comprising:
a semiconductor integrated circuit die; and
a substrate under said die, said substrate including a core, a via formed through said core, a metal plug fit in said via, and a metal foil on opposite sides of said core, said metal foil soldered to said plug.

17. The package of claim 16 including an adhesive between said foil and said core.

18. The package of claim 17 wherein said adhesive is cured.

19. The package of claim 16 wherein said plug is a copper plug and said metal foil is a copper foil.

20. The package of claim 16 wherein said plug includes a solder material formed on opposite sides of said plug.
